(19) United States
(12) Patent Application Publication
(10) Pub. No.: US 2018/0287018 A1
(43) Pub. Date: Oct. 4, 2018

(54) OPTOELECTRONIC COMPONENT

(71) Applicant: OSRAM Opto Semiconductors GmbH, Regensburg (DE)

(72) Inventors: Matthias Goldbach, Pentling (DE); Andreas Gruendl, Laaber (DE)

(21) Appl. No.: 15/764,938

(22) PCT Filed: Sep. 29, 2016
(86) PCT No.: PCT/EP2016/073314

§ 371 Date: Mar. 30, 2018

(30) Foreign Application Priority Data
Oct. 1, 2015 (DE) 10 2015 116 710.7

(51) Int. Cl. H01L 33/50

(52) U.S. Cl. CPC H01L 33/502; H01L 2933/0091

(57) ABSTRACT

An optoelectronic component includes a layer configured to generate an electromagnetic radiation including a first wavelength; a second layer including a conversion material and a scattering material, wherein the conversion material is configured to shift the first wavelength of the electromagnetic radiation to a second wavelength, and the scattering material is configured to scatter the first wavelength to a greater extent than the second wavelength.

### TECHNICAL FIELD

This disclosure relates to an optoelectronic component.

### BACKGROUND

Optoelectronic components in the form of LEDs, for example, that generate an electromagnetic radiation are known. The electromagnetic radiation comprises a first wavelength. The optoelectronic component comprises a conversion element that converts at least part of the electromagnetic radiation of the LED to a second wavelength.

There is nonetheless a need to provide an improved optoelectronic component.

### SUMMARY

We provide an optoelectronic component including a layer configured to generate an electromagnetic radiation including a first wavelength; a second layer including a conversion material and a scattering material, wherein the conversion material is configured to shift the first wavelength of the electromagnetic radiation to a second wavelength, and the scattering material is configured to scatter the first wavelength to a greater extent than the second wavelength.

We also provide an optoelectronic component including a layer configured to generate an electromagnetic radiation including a first wavelength; a second layer including a conversion material and a scattering material, wherein the conversion material is configured to shift the first wavelength of the electromagnetic radiation to a second wavelength, the scattering material is configured to scatter the first wavelength to a greater extent than the second wavelength, the scattering material includes quantum well particles, the second layer is configured as sedimented layer, the second layer includes a matrix material, the conversion material and the scattering material, and the scattering material includes a pyrogenic silica or an aerogel.

### BRIEF DESCRIPTION OF THE DRAWINGS

FIG. 1 shows a first example of a component including a layer including conversion material and scattering material.

FIG. 2 shows a second example of the component including a conversion layer and a scattering layer.

FIG. 3 shows a third example of the component including an optical element including scattering material.

FIG. 4 shows a further example of a component including a sedimented layer including conversion material and scattering material.

FIG. 5 shows a further example of the component including a sedimented conversion scattering layer.

FIG. 6 shows a further example including a further layer without diffusion material.

FIG. 7 shows a further example of a partial layer including conversion material and scattering material and including a further layer.

### LIST OF REFERENCE SIGNS

1 Component
2 Layer
3 Top side
4 Emission direction
5 Conversion material
6 Scattering material
7 Second layer
8 Matrix material
9 Conversion layer
10 Scattering layer
11 Optical element
12 Layer structure
13 Further layer
14 Partial layer

### DETAILED DESCRIPTION

We provide a component having an advantage of a more uniform mixing of a first and a second wavelength. In particular, a more uniform color mixing is achieved both in the far field and in the direct imaging. Moreover, the brightness losses are reduced. The more uniform mixing is achieved by virtue of the fact that a scattering material is provided, which scatters the first wavelength to a greater extent than the second wavelength. Scattering is understood to mean, in particular, diffuse scattering.

The conversion material and the scattering material are arranged in mixed fashion in a layer. A simple construction is achieved in this way.

The conversion material may be arranged in a conversion layer and the scattering material may be arranged in a scattering layer. The scattering layer may be arranged downstream of the conversion layer in an emission direction of the electromagnetic radiation. As a result of the bipartite configuration, the conversion layer and the scattering layer may be produced independently of one another. Simple manufacture of the component is thus possible.

An optical element, for example, in the form of a lens, is provided, which guides the electromagnetic radiation. The optical element comprises a scattering material. A further improvement in the scattering of the first wavelength is achieved in this way.

The scattering material may comprise particles comprising a size that is smaller than a wavelength in the first wavelength range. In particular, the particles comprise a size that is smaller than half a wavelength in the first wavelength range, in particular smaller than one third of the wavelength in the first wavelength range.

The scattering material may be configured in the form of quantum well particles.

The layer may be configured as sedimented layer, wherein the sedimented layer comprises a matrix material, the conversion material and the scattering material. Simple production of the layer may be achieved in this way. Moreover, a desired arrangement of the conversion material and the scattering material may be achieved with the aid of the sedimentation.

The density distribution of the conversion material may decrease with increasing distance from the layer generating the electromagnetic radiation in an emission direction of the electromagnetic radiation. In particular, a density distribution of the scattering material may increase with increasing distance from the layer generating the electromagnetic radiation in an emission direction of the electromagnetic radiation.

The scattering material may be configured in the form of pyrogenic silica or in the form of aerogel. An efficient diffuse scattering may be achieved as a result.

The scattering material may be configured to comprise a higher scattering effect for blue light. Moreover, the conversion material may be configured to convert blue light into yellow or green light.

The scattering material may be configured to comprise a higher scattering effect for green light. Moreover, the conversion material may be configured to convert green light into red light.

The scattering material and the conversion material may be arranged in a partial layer of the layer. In this case, a further part of the layer, in particular an upper part of the layer in the emission direction, is free of conversion material and of scattering material. The partial layer may also be configured in the form of a conversion layer comprising scattering material.

The above-described properties, features and advantages and the way in which they are achieved will become clearer and more clearly understood in association with the following description of the examples which are explained in greater detail in association with the drawings.

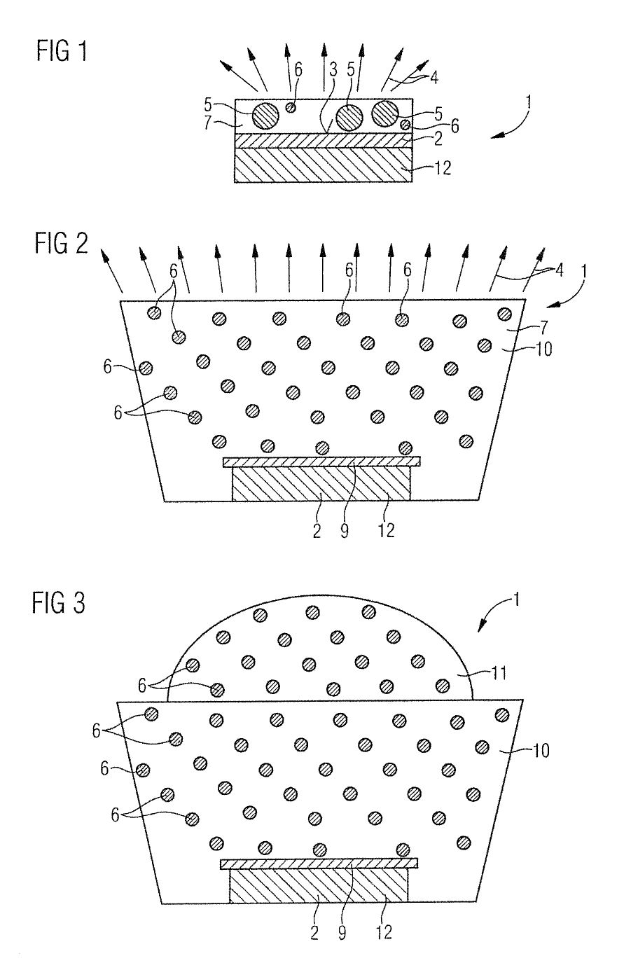

FIG. 1 shows, in a schematic sectional illustration, an optoelectronic component 1 comprising a layer structure 12 comprising a layer 2 configured to generate an electromagnetic radiation comprising a first wavelength range comprising at least one first wavelength. The layer structure 12 and the layer 2 may be configured, for example, in the form of a semiconductor chip. By way of example, the layer structure 12 comprising the layer 2 may be configured as a light emitting diode (LED). In the example illustrated, the layer 2 is configured to emit electromagnetic radiation at various emission angles via a top side 3. A second layer 7 comprising conversion material 5 and scattering material 6 is arranged in the emission direction 4. The conversion material 5 and the scattering material 6 are arranged in a matrix material 8 in the second layer 7. The matrix material may be silicone, for example. The conversion material 5 is illustrated schematically in the form of large circular areas and the scattering material 6 is illustrated schematically in the form of small circular areas. The second layer 7 may be produced by spray coating, for example. A further layer comprising only matrix material 8 and no scattering material and no conversion material may be arranged above the second layer 7.

The conversion material 5 is configured to shift electromagnetic radiation in the first wavelength range to a second wavelength in a second wavelength range. By way of example, a phosphor may be used as conversion material 5. The scattering material 6 is configured to scatter the first wavelength to a greater extent than the second wavelength. Scattering to a greater extent is understood to mean an at least 10% higher scattering probability, in particular a 50% higher scattering probability. Moreover, scattering to a greater extent may be understood to mean an angular deflection that is greater by 10% on average.

The electromagnetic radiation comprising the first wavelength may be blue light, for example. The conversion material is configured, for example, to emit yellow light after having been excited by the blue light. A mixture of blue and yellow light appears as white light. In surface emitters that typically emit as lambertian emitters, all the more blue light is converted into yellow light, the more obliquely the light ray passes through the second layer 7 comprising the conversion material. This results in an unequal color distribution over the emission angle. To reduce the unequal color distribution, the scattering material 6 is configured to scatter at least one first wavelength in the first wavelength range to a greater extent than a second wavelength in the second wavelength range. The scattering material lengthens an effective path length of the electromagnetic radiation comprising the first wavelength through the layer, without lengthening the path length of the converted electromagnetic radiation comprising the second wavelength in the second wavelength range.

The scattering material 6 is dimensioned with regard to the particle size for Rayleigh scattering such that the first wavelength is scattered to a greater extent than the second wavelength. In this case, the scattering material comprises particles comprising in particular in all dimensions a size smaller than a wavelength in the first wavelength range. In particular, the particles comprise a size that in particular in all dimensions is smaller than half a wavelength in the first wavelength range, in particular smaller than one third of the wavelength in the first wavelength range.

Moreover, the scattering material 6 may be configured in the form of quantum well particles that absorb the first wavelength to a greater extent and emit diffusely in all spatial directions. A homogenization of the light mixing even over various emission angles is achieved with the aid of the proposed second layer 7.

In a desired complete conversion of the electromagnetic radiation comprising the first wavelength in the first wavelength range into an electromagnetic radiation comprising a second wavelength in the second wavelength range, addition of a scattering material that is selective for the first wavelength range, in particular the first wavelength, makes it possible to reduce a concentration of conversion material that is required in absolute terms.

FIG. 2 shows a further example of the component 1, wherein the conversion material 5 is arranged in a conversion layer 9. A scattering layer 10 comprising scattering material 6 is arranged above the conversion layer 9. The layer structure 12 comprising the layer 2 may also be surrounded laterally by the conversion layer 9.

FIG. 3 shows a further example that substantially corresponds to FIG. 2, but wherein an optical element 11 in the form of a lens is additionally arranged. The lens may also comprise scattering material 6. In the example in which scattering material 6 is contained in the optical element 11, the scattering layer 10 or the scattering material 6 in the scattering layer 10 may also be dispensed with or provided in a reduced concentration.

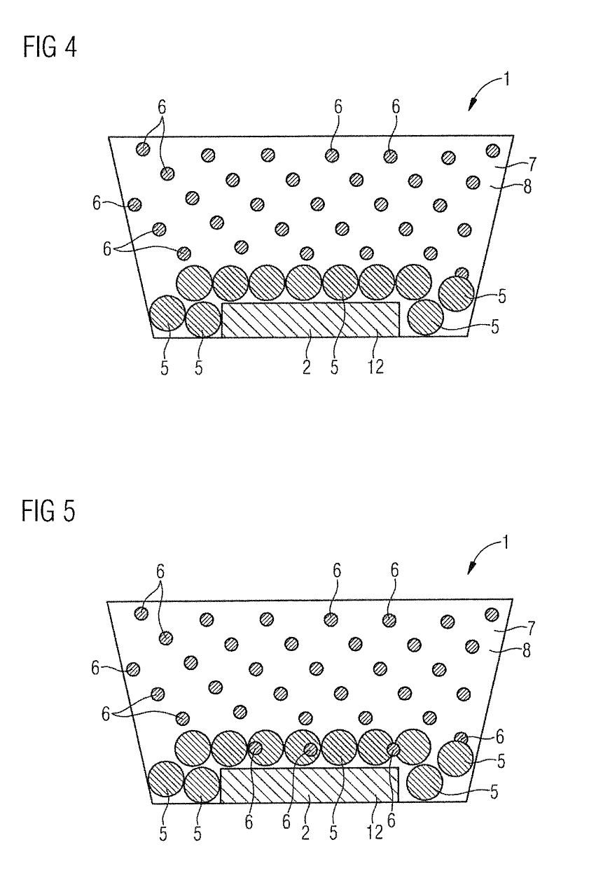

FIG. 4 shows a further example in which the layer 2 comprising the layer structure 12 is embedded into a second layer 7. The second layer 7 comprises matrix material 8, conversion material 5 and scattering material 6. The layer 7 is produced by a sedimentation method, a spray coating method or a potting method, wherein the conversion material 5, on account of its own concentration, the concentration of the scattering material, the concentration of a pyrogenic silica and the process control, settles more rapidly and is arranged with increased density both on the top side 3 of the layer 2 and at side faces of the layer structure 12. A pyrogenic silica or an aerogel may be used as scattering material. The scattering material 6 is arranged in the matrix material 8 above the conversion material 5 in the emission direction.

FIG. 5 shows a further example of a second layer 7 produced with the aid of a sedimentation method, with the aid of a spray coating method, or with the aid of potting method. In this example, the matrix material 8, the conversion material 5 and the scattering material 6 are chosen such that a mixture of conversion material 5 and scattering material 6 is established on the top side 3 of the layer 2.

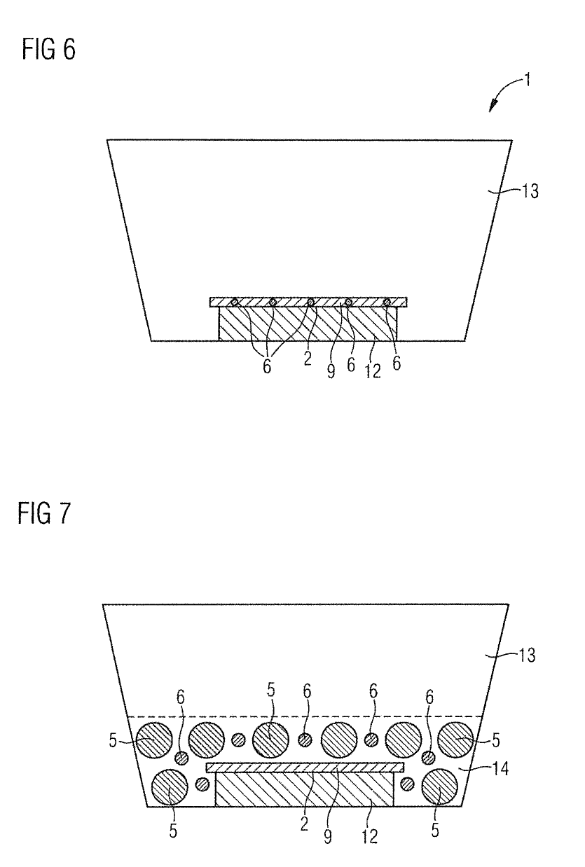

FIG. 6 shows a further example that substantially corresponds to FIG. 5, but wherein the scattering material 6 and the conversion material 5 are contained in a conversion layer 9. The conversion layer 9 is arranged directly above the second layer 2. Moreover, the conversion layer 9 is covered with a further layer 13 comprising, for example, a potting material, in particular comprising matrix material free of conversion material and scattering material. The matrix material 8 and the further layer 13 are optically transmissive to the electromagnetic radiation of the layer 2.

FIG. 7 shows a further example of the component 1, wherein the optically active layer 2 is covered with a partial layer 14, wherein the partial layer 14 comprises matrix material, conversion material 5 and scattering material 6. A further layer 13 is arranged above the partial layer 14 in the emission direction, the further layer consisting, for example, of a potting material, in particular of matrix material, and comprising no scattering material and no conversion material. The partial layer 14 and the further layer 13 constitute a second layer 7. Optical elements for guiding the electromagnetic radiation may be provided in the examples in FIGS. 6 and 7 as well.

The conversion material 5 may comprise various phosphors in all the examples. In this case, e.g., a blue electromagnetic radiation generated by an LED, for example, may be combined with one or more phosphors as conversion material. The matrix material, e.g., silicone, contains, e.g., small amounts of a phosphor based, for example, on yttrium aluminum garnet (YAG) or alkaline earth metal orthosilicate (BOSE).

The scattering material 6 may be configured, for example, in the form of an aerogel in all the examples. Moreover, the scattering layer 10 may likewise be configured in the form of an aerogel or comprise at least one aerogel.

Aerogels comprise a highly dendritic structure, that is to say a branching of particle chains with very many interspaces in the form of open pores. These chains have contact points such that ultimately the pattern of a stable, sponge-like network is obtained. The pore size is in the nanometers range and the specific surface areas may become extremely high at up to 1,000 m² per gram.

A silicate aerogel may comprise the following chemical composition: SiO(OH)y(OR)z, where y and z are parameters dependent on the production process. The silicate aerogels comprise a high optical transparency and comprise a refractive index of approximately 1.007 to 1.24 with a typical value of 1.02. Silicate aerogels, in particular, on account of the silicon dioxide, scatter shorter wavelengths, i.e., blue portions of the light, to a greater extent than longer wavelengths.

The individual particles of the silicate aerogels are around one to ten nanometers in size and the distance between the chains is approximately 10 to 100 nm. The cylindrical mesopores have a diameter of 2 nm to 50 nm, wherein the porosity is 80 to 99.8%. The apparent density consequently is 0.16 to

$$500 \frac{mg}{{cm}^{3}}$$

with a typical value of

$$100 \frac{mg}{{cm}^{3}} ,$$

whereas the pure density (base material without pores) is at 1700 to

$$2100 \frac{mg}{{cm}^{3}} .$$

Accordingly, silicate aerogels comprise a very high specific surface area with a value of 100 to

$$1600 \frac{{m}^{2}}{g}$$

and a typical value of

$$600 \frac{{m}^{2}}{g} .$$

The thermal conductivity in air at 300 kelvins is extremely low with a value of 0.017 to

$$0.021 \frac{W}{m \cdot K}$$

and a typical value of

$$0.02 \frac{W}{m \cdot K} .$$

Silicate aerogels may scarcely be wetted or chemically attacked by liquid metals. Their melting point is approximately 1200° C. Moreover, they are non-combustible and non-toxic. The modulus of elasticity is 0.002 to 100 MPa, with a typical value of 1 MPa. Other types of aerogels may also be used instead of silicate aerogels.

Various conversion materials and/or scattering materials may be used depending on the desired color distribution and/or the desired distribution of the electromagnetic radiations.

The layer 2 may also generate different wavelengths than blue light, for example, green light.

With the aid of the proposed components, it is possible to reduce light losses during a partial conversion of the electromagnetic radiation comprising the first wavelength into the second wavelength and to homogenize a light mixing of the different wavelengths over the emission angle. A color locus over the emission angle is thus far more constant.

Quantum well particles are understood to be particles comprising an optically active layer that may absorb light and emit it in a different wavelength. The optically active layer comprises a size smaller than the desired absorption wavelength, i.e., the wavelength in the first wavelength range. In this case, the size of the optically active layer may be smaller than the absorption wavelength in one, two or all three dimensions. The optically active layer may also be embedded into some other material. Titanium dioxide, for example, may be used as scattering material. However, other scattering materials are also possible.

Although our components have been more specifically illustrated and described in detail by preferred examples, nevertheless this disclosure is not restricted by the examples disclosed and other variations may be derived therefrom by those skilled in the art, without departing from the scope of protection of the appended claims.

This application claims priority of DE 10 2015 116 710.7, the subject matter of which is incorporated herein by reference.

1-13. (canceled)

14. An optoelectronic component comprising:
a layer configured to generate an electromagnetic radiation comprising a first wavelength;
a second layer comprising a conversion material and a scattering material,
wherein the conversion material is configured to shift the first wavelength of the electromagnetic radiation to a second wavelength, and
the scattering material is configured to scatter the first wavelength to a greater extent than the second wavelength.

15. The component according to claim 14, wherein the conversion material and the scattering material are mixed in the second layer.

16. The component according to claim 14, wherein the conversion material is arranged in a conversion layer and the scattering material is arranged in a scattering layer, and the scattering layer is arranged downstream of the conversion layer in an emission direction.

17. The component according to claim 14, further comprising an optical element that guides the electromagnetic radiation, wherein the optical element comprises scattering material.

18. The component according to claim 14, wherein the scattering material comprises particles comprising a size smaller than a wavelength in the first wavelength range.

19. The component according to claim 14, wherein the scattering material comprises quantum well particles.

20. The component according to claim 14, wherein the second layer is configured as sedimented layer, and the second layer comprises a matrix material, the conversion material and the scattering material.

21. The component according to claim 14, wherein a density distribution of the conversion material decreases with increasing distance from the layer in an emission direction of the electromagnetic radiation.

22. The component according to claim 14, wherein a density distribution of the scattering material increases with increasing distance from the layer in an emission direction of the electromagnetic radiation.

23. The component according to claim 14, wherein the scattering material comprises a pyrogenic silica or an aerogel.

24. The component according to claim 14, wherein the scattering material comprises a higher scattering effect for blue light, the conversion material is configured to convert blue light into yellow light, and the layer is configured to emit blue light.

25. The component according to claim 14, wherein the scattering material comprises a higher scattering effect for green light, the conversion material is configured to convert green light into red light, and the layer is configured to emit green light.

26. The component according to claim 14, wherein the scattering material and the conversion material are arranged in a partial layer, the partial layer is arranged above the layer, a further layer is provided above the partial layer in the emission direction, and the further layer is free of conversion material and free of scattering material.

27. The component according to claim 14, wherein the scattering material comprises quantum well particles, the second layer is configured as sedimented layer, and the second layer comprises a matrix material, the conversion material and the scattering material.

28. The component according to claim 14, wherein the scattering material comprises quantum well particles, and a density distribution of the conversion material decreases with increasing distance from the layer in an emission direction of the electromagnetic radiation.

29. The component according to claim 14, wherein the scattering material comprises quantum well particles, and a density distribution of the scattering material increases with increasing distance from the layer in an emission direction of the electromagnetic radiation.

30. The component according to claim 14, wherein the second layer is configured as sedimented layer, the second layer comprises a matrix material, the conversion material and the scattering material, the scattering material comprises quantum well particles, and a density distribution of the conversion material decreases with increasing distance from the layer in an emission direction of the electromagnetic radiation.

31. An optoelectronic component comprising:
a layer configured to generate an electromagnetic radiation comprising a first wavelength;
a second layer comprising a conversion material and a scattering material,
wherein the conversion material is configured to shift the first wavelength of the electromagnetic radiation to a second wavelength,
the scattering material is configured to scatter the first wavelength to a greater extent than the second wavelength,
the scattering material comprises quantum well particles,
the second layer is configured as sedimented layer,
the second layer comprises a matrix material, the conversion material and the scattering material, and
the scattering material comprises a pyrogenic silica or an aerogel.
